(19) United States
(12) Patent Application Publication
(10) Pub. No.: US 2013/0049222 A1
(43) Pub. Date: Feb. 28, 2013

(54) SEMICONDUCTOR DEVICE AND METHOD OF MANUFACTURING THE SAME

(71) Applicant: Won Sic WOO, Gyeonggi-do (KR)

(72) Inventor: Won Sic WOO, Gyeonggi-do (KR)

(21) Appl. No.: 13/565,863

(22) Filed: Aug. 3, 2012

(30) Foreign Application Priority Data
Aug. 30, 2011 (KR) 10-2011-0087134

(51) Int. Cl. H01L 23/48; H01L 21/265

(52) U.S. Cl. 257/774; 438/527; 257/E23.011; 257/E21.334

(57) ABSTRACT

A method of manufacturing a semiconductor device includes forming select lines extending in a second direction crossing a first direction on a semiconductor substrate, wherein the semiconductor substrate has active regions separated by an isolation layer and extending in the first direction, forming junctions by implanting first impurities into the active regions, respectively, between the select lines and forming a plurality of oxide layers filled between the select lines, forming contact holes exposing the junctions by etching at least one of the plurality of oxide layers, forming junction extensions by implanting second impurities into the active regions of the semiconductor substrate exposed due to loss of the isolation layer while the contact holes are formed, and forming contact plugs for filling the contact holes.

### CROSS-REFERENCE TO RELATED APPLICATION

Priority is claimed to Korean patent application number 10-2011-0087134 filed on Aug. 30, 2011, the entire disclosure of which is incorporated herein by reference in its entirety.

### BACKGROUND

1. Field of Invention

Exemplary embodiments of the present invention relate to a semiconductor device and a method of manufacturing the same and, more particularly, to a flash memory device and a method of manufacturing the same.

2. Description of Related Art

In order to have a higher integration degree of semiconductor devices, a flash memory device has a cell array that includes string structures. Each of the string structures has a plurality of cell transistors coupled in series between select transistors. With increasing integration degree of a string structure, the widths of a source region and a drain region become smaller, which results in increased resistance of the source region and the drain region and increased processing difficulty. Therefore, a method of improving the stability and reliability of a highly-integrated flash memory device is useful.

### BRIEF SUMMARY

Exemplary embodiments relate to a semiconductor device and a method of manufacturing the same that can improve the stability and reliability of a flash memory device.

A semiconductor device according to an embodiment of the present invention includes a semiconductor substrate including active regions extending in a first direction, select lines provided on the semiconductor substrate in a second direction crossing the first direction, junctions provided on the active regions, respectively, between the select lines and including first impurities, a plurality of oxide layers filling spaces between the select lines, junction extensions coupled under the junctions and provided on the active regions of the semiconductor substrate, wherein the junction extensions include second impurities, and contact plugs passing through at least one of the plurality of oxide layers and coming in contact with the junctions and the junction extensions.

A method of manufacturing a semiconductor device according to an embodiment of the present invention includes forming select lines extending in a second direction crossing a first direction on a semiconductor substrate, wherein the semiconductor substrate has active regions separated by an isolation layer and extending in the first direction, forming junctions by implanting first impurities into the active regions, respectively, between the select lines and forming a plurality of oxide layers filled between the select lines, forming contact holes exposing the junctions by etching at least one of the plurality of oxide layers, forming junction extensions by implanting second impurities into the active regions of the semiconductor substrate exposed due to loss of the isolation layer while the contact holes are formed, and forming contact plugs for filling the contact holes.

### BRIEF DESCRIPTION OF THE DRAWINGS

FIG. 1 a layout view of a semiconductor device according to embodiments of the present invention;

FIGS. 2A to 2L are cross-sectional views of a semiconductor device according to a first embodiment of the present invention and a method of manufacturing the same;

FIGS. 3A to 3J are cross-sectional views of a semiconductor device according to a second embodiment of the present invention and a method of manufacturing the same;

FIG. 4 is a cross-sectional view of the semiconductor device according to the second embodiment of the present invention, taken in a direction of a source contact line; and

FIG. 5 is a schematic block diagram of a memory system according to an exemplary embodiment of the present invention.

### DESCRIPTION OF EMBODIMENTS

Hereinafter, various embodiments of the present disclosure will be described in detail with reference to the accompanying drawings. The figures are provided to allow those having ordinary skill in the art to understand the scope of the embodiments of the disclosure.

In the following description, it will be understood that when a layer is referred to as being ‘on’ another layer or semiconductor substrate, it can be directly on the other layer or the semiconductor substrate, or a third layer may also be interposed therebetween. In the drawings, the thickness and size of each layer are exaggerated for clarity and illustration purposes. Like reference numerals in the drawings denote like elements.

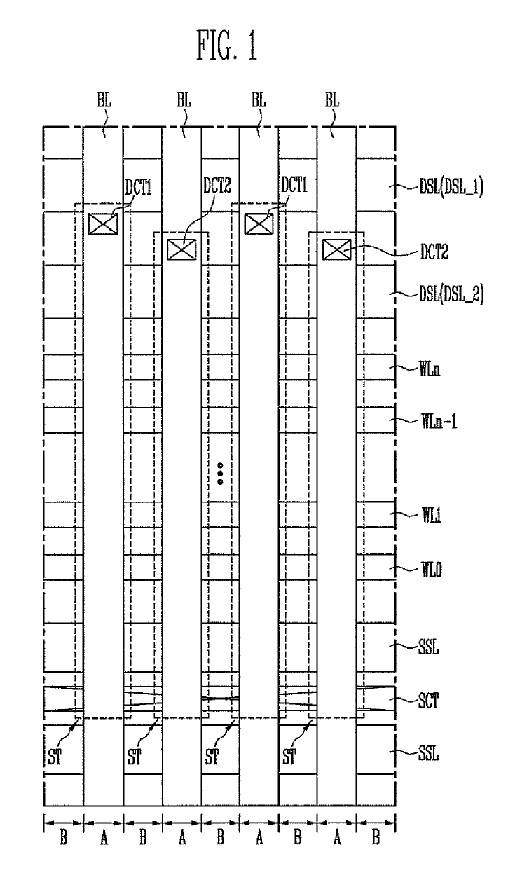

FIG. 1 is a layout view of a semiconductor device according to embodiments of the present invention. FIG. 1 particularly illustrates a portion of a cell array region of a NAND flash memory device.

Referring to FIG. 1, a cell array of the semiconductor device according to the embodiments of the present invention includes a semiconductor substrate that has isolation regions B and active regions A defined therein. The isolation regions B and the active regions A alternate with each other and are arranged next to each other in a first direction. The active regions A are separated by isolation trenches and isolation layers formed in the isolation regions B.

Gate lines (SSL, WL0 to WLn, and DSL) are arranged in a second direction crossing the isolation regions B and the active regions A. These gate lines include drain select lines DSL, source select lines SSL, and word lines WL0 to WLn. The drain select lines DSL are arranged next to each other, and the source select lines SSL are arranged next to each other. The word lines WLO to WLn are disposed between the adjacent drain select line DSL and source select line SSL.

The active regions A between the gate lines (SSL, WL0 to WLn, and DSL) are defined as junctions into which impurities are implanted. Here, a junction between the drain select lines DSL is defined as a drain region of the string structure ST, whereas a junction between the source select lines SSL is defined as a source region of the string structure ST.

A drain select transistor formed at an intersection between the drain select line DSL and the active region A, a source select transistor formed at an intersection between the source select line SSL and the active region A, and a plurality of memory cell transistors formed at intersections between the word lines WL0 to WLn and the active region A are coupled in series with each other to form a single string structure ST. The string structures ST are connected to bit lines BL, respectively, through drain contact plug formed in a first drain contact region DCT1 or a second drain contact region DCT2. In addition, each of the string structures ST is connected to metal wiring (not shown) to which a common source voltage is applied through a source contact line formed on a source contact region SCT.

The bit lines BL and the metal wiring are coupled to driving transistors of peripheral circuits formed in the peripheral region, so as to apply voltages used to drive the cell array.

The first and second drain contact regions DCT1 and DCT2 are arranged on top of the active regions A, respectively, arranged between the drain select lines DSL in a direction in which the drain select lines DSL extend. In addition, the first and second drain contact regions DCT1 and DCT2 are arranged in a zigzag pattern to increase the distance between the first and second drain contact regions DCT1 and DCT2 and thus prevent electrical connections therebetween. That is, the first and second drain contact regions DCT1 and DCT2 are arranged in two rows, which consist of first and second rows, in the direction in which the drain select lines DSL extend. The first drain contact regions DCT1 in the first row are closer to a first drain select line DSL_1 than to a second drain select line DSL_2. In addition, the first drain contact regions DCT1 are disposed on top of odd-numbered active regions among the active regions A arranged in the direction in which the drain select lines DSL extend. The second drain contact regions DCT2 in the second row are closer to the second drain select line DSL_2 than to the first drain select line DSL_1. In addition, the second drain contact regions DCT2 are disposed on top of even-numbered active regions among the active regions arranged in the direction in which the drain select lines DSL extend.

The source contact regions SCT extend in a direction parallel to the source select lines SSL and are disposed on top of the isolation regions B and the active regions A between the source select lines SSL. The source contact line formed on the source contact region SCT is commonly coupled to a plurality of source regions formed in the plurality of active regions A between the source select lines SSL.

Hereinafter, a method of manufacturing the semiconductor device, shown in FIG. 1, will now be described.

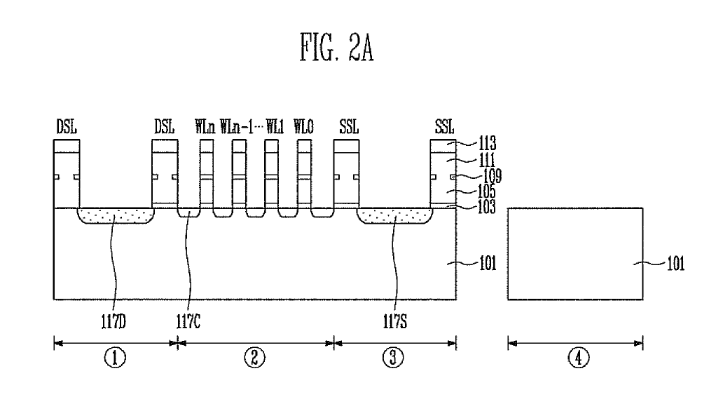

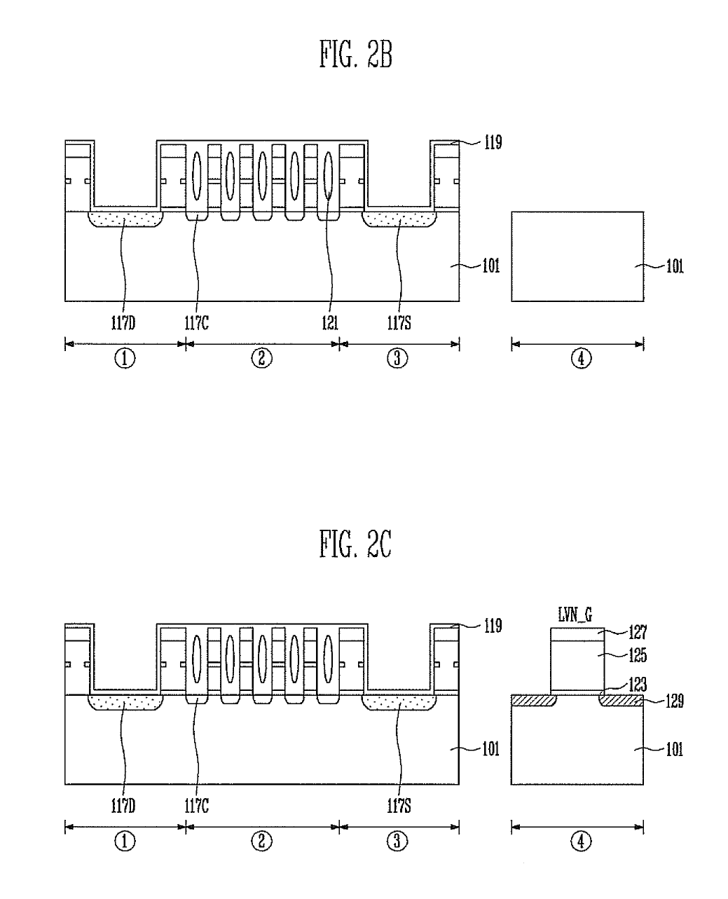

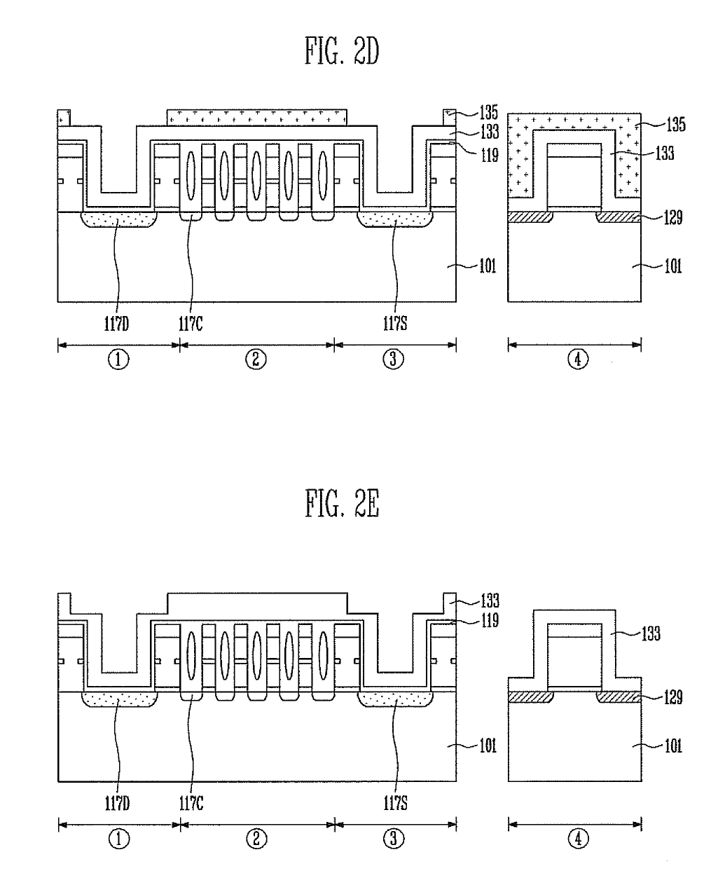

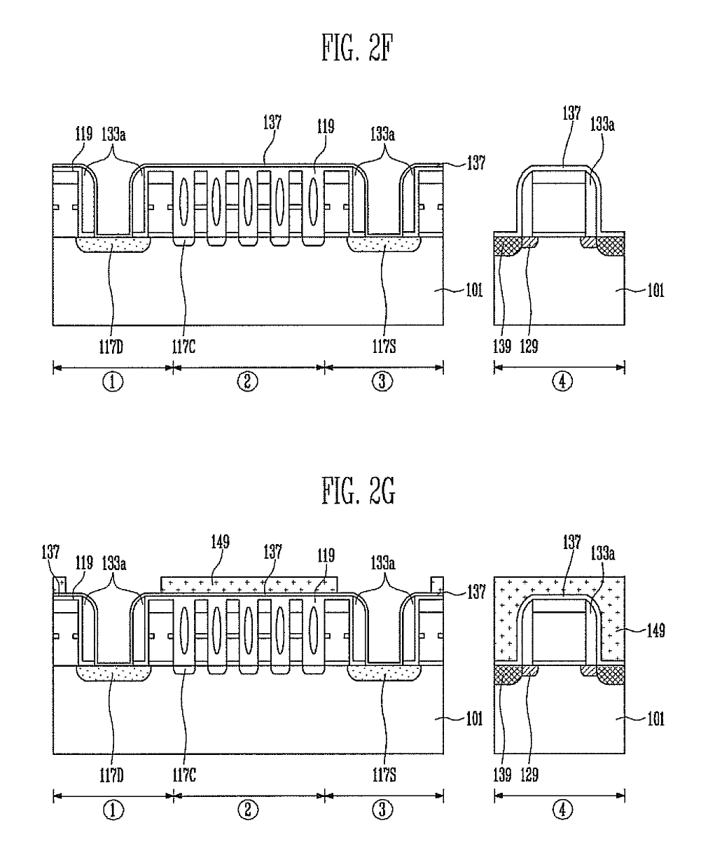

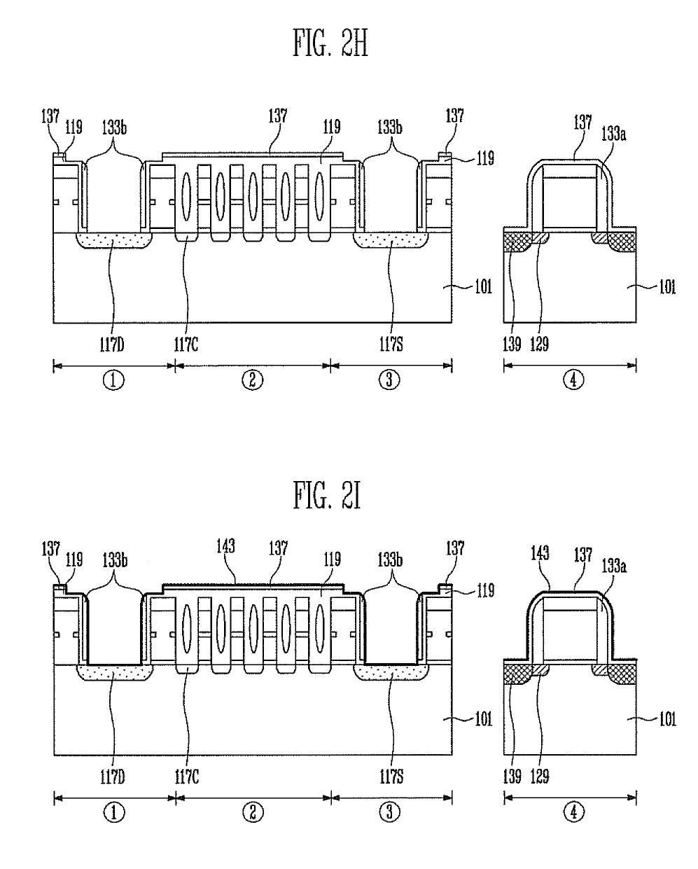

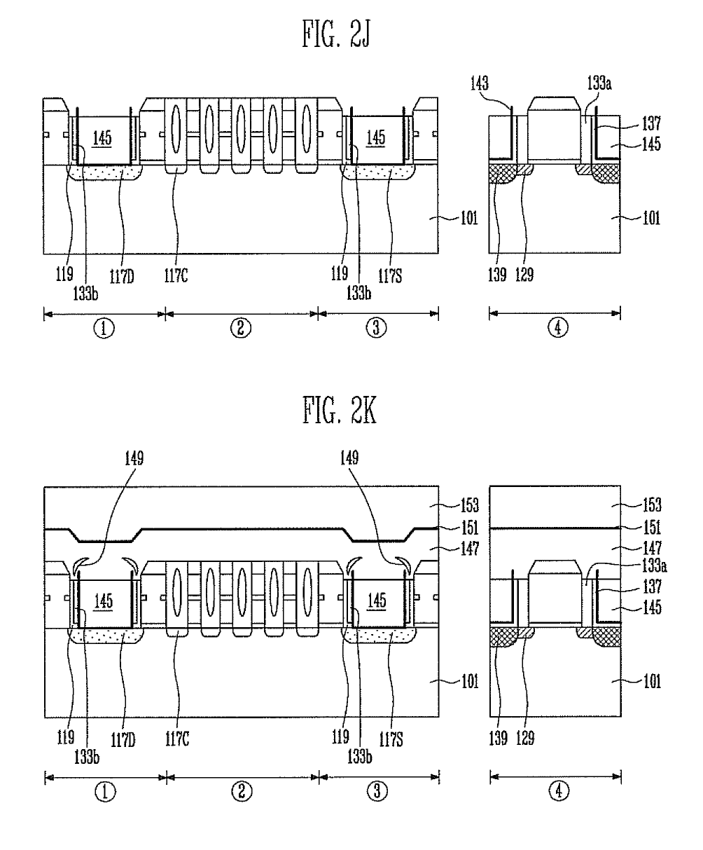

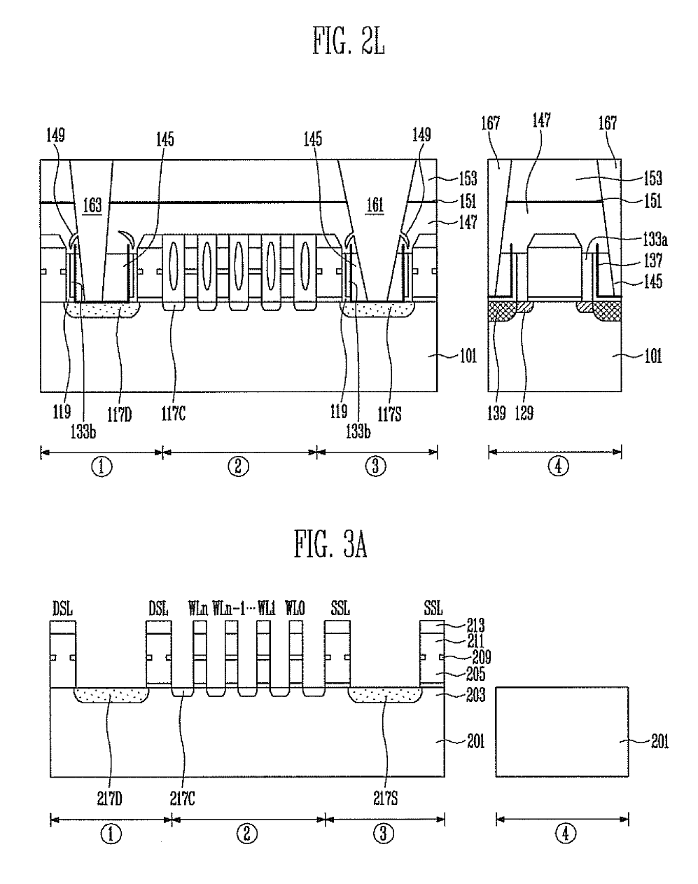

FIGS. 2A to 2L are cross-sectional views of a semiconductor device according to a first embodiment of the present invention and a method of manufacturing the same.

Referring to FIG. 2A, the gate lines (SSL, WL0 to WLn, and DSL) are formed on top of a semiconductor substrate 101 that includes first to fourth regions \textcircled{1}, \textcircled{2}, \textcircled{3}, and \textcircled{4}. The first region \textcircled{1} is defined as a region in which the drain select lines DSL will be formed and a region between the adjacent drain select lines DSL. The second region \textcircled{2} is defined as a region between the adjacent drain select line DSL and source select line SSL. The third region \textcircled{3} is defined as a region in which the source select lines SSL will be formed and a region between the adjacent source select lines SSL. The fourth region \textcircled{4} is defined as a peripheral region. In FIGS. 2A to 2L, for example, only the region in which a low voltage NMOS transistor being driven at a relatively low voltage is be formed is illustrated as the fourth region \textcircled{4} for illustration purposes. Hereinafter, the first and third regions \textcircled{1} and \textcircled{3} are referred as select transistor regions, the second region \textcircled{2} is referred to as a cell region, and the fourth region \textcircled{4} is referred to as a peripheral region.

A method of forming the gate lines (SSL, WL0 to WLn, and DSL) on top of the semiconductor substrate 101 is described in more detail. In a NAND flash memory device, the gate lines including the drain select lines DSL, the word lines WL0 to WLn, and the source select lines SSL are formed on top of the semiconductor substrate 101.

The following processes may be performed to form the gate lines (SSL, WL0 to WLn, and DSL). The gate lines (SSL, WL0 to WLn, and DSL) may be formed by using a spacer patterning technology to achieve higher integration of the device.

First, a well (not shown) is formed in the semiconductor substrate 101, and a gate stack structure is formed on top of the semiconductor substrate 101. The gate stack structure has a tunnel insulating layer 103, a first silicon layer 105, a dielectric layer 109, and a second silicon layer 111 that are sequentially stacked in that order, respectively. To form the gate stack structure, first, the tunnel insulating layer 103 is formed over the entire surface of the semiconductor substrate 101. The first silicon layer 105 is formed over the tunnel insulating layer 103. The first silicon layer 105 may be a single layer formed of an undoped polysilicon layer or a doped polysilicon layer or may have an undoped polysilicon layer and a doped polysilicon layer that are stacked. A trivalent impurity or a pentavalent impurity may be added to the doped polysilicon layer.

Subsequently, the first silicon layer 105 is etched by an etch process using an isolation mask that defines the isolation regions B as an etch mask. In this manner, the first silicon layer 105 is patterned into a plurality of silicon lines in parallel with each other. Next, the tunnel insulating layer 103 and the semiconductor substrate 101 are etched to form trenches in the form of parallel lines in the isolation regions B. Subsequently, an insulating layer is formed such that the trenches may be filled with the insulating layer, and the insulating layer on the isolation mask is removed such that the insulating layer may be left, for example, only in the trenches and on the trenches. In this manner, the isolation layer is formed.

After the isolation mask is removed, the dielectric layer 109 is formed over the entire structure. The dielectric layer 109 has an oxide layer, a nitride layer, and an oxide layer that are stacked. The oxide layer or the nitride layer may be replaced by an insulating layer that has a higher dielectric constant than itself. A portion of the dielectric layer 109 is etched in the region in which the drain and source select lines DSL and SSL will be formed. As a result, a portion of the first silicon layer 105 is exposed in the region in which each of the drain and source select lines DSL and SSL will be formed.

The second silicon layer 111 is formed over the dielectric layer 109. According to an example, the second silicon layer 111 may be formed of a doped polysilicon layer. In this manner, the gate stack structure is formed.

A hard mask layer 113 is formed over the gate stack structure. Subsequently, the hard mask layer 113, the second silicon layer 111, and the dielectric layer 109 are patterned in a direction crossing the silicon lines formed by patterning the first silicon layer 105. The dielectric layer 109 and the first silicon layer 105 are subsequently etched. As a result, the gate lines (SSL, WL0 to WLn, and DSL) crossing the active regions A and the isolation regions B are formed on the semiconductor substrate 101.

While a portion of the dielectric layer 109 is etched, the second silicon layer 111 is formed. Therefore, the first silicon layer 105 and the second silicon layer 111 on the drain and source select lines DSL and SSL are coupled to each other through the etched portion of the dielectric layer 109.

The distances between the adjacent word lines WL0 to WLn, the distance between the adjacent word line WL0 and source select line SSL, and the distance between the adjacent word line WLn and drain select line DSL are shorter than the distance between the adjacent drain select lines DSL and the distance between the adjacent source select lines SSL.

Cell junctions 117C are defined in the semiconductor substrate 101 in the cell region \textcircled{2}, which is opened by the gate lines (SSL, WL0 to WLn, and DSL). In addition, a drain region 117D is defined in the semiconductor substrate 101 in the select transistor region \textcircled{1}, which is opened between the drain select lines DSL. Also, a source region 117S is defined in the semiconductor substrate 101 in the select transistor region \textcircled{3}, which is opened between the source select lines SSL. After the gate lines (SSL, WL0 to WLn, and DSL) are formed, impurities are implanted into the cell junctions 117C. While the impurities are being implanted into the cell junctions 117C, the peripheral region \textcircled{4} is blocked by a photoresist pattern, and the impurities may also be implanted into the source and drain regions 117S and 117D. Examples of the impurities implanted into the cell junction 117C may include N type impurities.

Subsequently, impurities are implanted into the source and drain regions 117S and 117D. While the impurities are implanted into the source and drain regions 117S and 117D, the peripheral region \textcircled{4} and the cell region \textcircled{2} are blocked by the photoresist pattern. Examples of the impurities implanted into the source and drain regions 117S and 117D may include P type impurities for counter doping.

Referring to FIG. 2B, a first insulating layer 119 is formed over the entire structure including the gate lines (SSL, WL0 to WLn, and DSL). According to an example, the first insulating layer 119 may be formed of an insulating layer that has an overhang structure that allows air-gaps 121 to be formed in the cell region \textcircled{2} between the gate lines (SSL, WL0 to WLn, and DSL). For example, the first insulating layer 119 is formed of a disilane-high temperature oxide (DS-HTO). The distance between the source select line SSL and the word line WL0, the distance between the drain select line DSL and the word line WLn, and the distances between the word lines WL0 to WLn are shorter than the distance between the drain select lines DSL and the distance between the source select lines SSL. In addition, during the process of forming the first insulating layer 119, overhangs are formed at the top corners of the gate lines (DSL, SSL, and WL0 to WLn). For these reasons, the first insulating layer 119 does not completely fill the space between the source select line SSL and the word line WL0, the space between the drain select line DSL and the word line WLn, and the spaces between the word lines WL0 to WLn, and therefore the air-gaps 121 are formed therein. The drain select lines DSL are spaced apart by a relatively large distance, and the source select lines SSL are also spaced apart by a relatively large distance. Therefore, the first insulating layer 119 is formed between the drain select lines DSL and the source select lines SSL along the steps on the drain and select lines DSL and SSL.

The first insulating layer 119 may be non-uniform in thickness across the semiconductor substrate 101. That is, the thickness of the first insulating layer 119 may be different in various regions of the semiconductor substrate 101. The thickness of the first insulating layer 119 over the source region 117S and the drain region 117D may vary in different regions of the semiconductor substrate 101.

Referring to FIG. 2C, after an annealing process is performed to activate the impurities implanted into the cell junction 117C, the source region 117S, and the drain region 117D, a process is performed such that a gate line LVN_G may be formed on top of the semiconductor substrate 101 in the peripheral region \textcircled{4}.

In order to form the gate line LVN_G on the semiconductor substrate 101 in the peripheral region \textcircled{4}, a gate insulating layer 123 and a gate conductive layer 125 are stacked on top of the semiconductor substrate 101 in the peripheral region \textcircled{4}. After a gate mask pattern 127 is formed over the gate conductive layer 125 in the peripheral region \textcircled{4}, the gate conductive layer 125 is patterned to form the gate line LVN_G in the peripheral region \textcircled{4}.

Subsequently, impurities are implanted into the source region and the drain region defined on both sides of the gate line LVN_G in the peripheral region \textcircled{4} to form a lightly doped drain (LDD) region 129.

Referring to FIG. 2D, a second insulating layer 133 for a spacer is formed on the surface of the entire structure including the LDD region 129. The second insulating layer 133 is an insulating layer used to form spacers that block a portion of the LDD region 129 adjacent to the gate line LVN_G in the peripheral region \textcircled{4}. The second insulating layer 133 has a thickness greater than that of the first insulating layer 119.

The total thickness of the first and second insulating layers 119 and 133 formed on the source region 117S between the source select lines SSL and the drain region 117D between the drain select lines DSL is to be controlled to a thickness that allows impurities to be implanted to a target depth when the impurities are implanted into the source region 117S and the drain region 117D in a subsequent process. Therefore, a first mask pattern 135 that exposes a portion of the second insulating layer 133 between the drain and source select lines DSL and SSL is formed to remove the portion of the second insulating layer 133 formed on the source region 117S between the source select lines SSL and the drain region 117D between the drain select lines DSL. The first mask pattern 135 may be a photoresist pattern.

Referring to FIG. 2E, the portion of the second insulating layer 133 exposed through the first mask pattern 135 is etched by wet etching to reduce the thickness of the second insulating layer 133. As a result, the total thickness of the first and second insulating layers 119 and 133 formed on the source region 117S between the source select lines SSL and the drain region 117D between the drain select lines DSL is controlled to a target thickness.

Subsequently, impurities are implanted into the source region 117S between the source select lines SSL and the drain region 117D between the drain select lines DSL so as to reduce resistance of the source and drain regions 117S and 117D. By this point, the total thickness of the first and second insulating layers 119 and 133 formed on the source region 117S between the source select lines SSL and the drain region 117D between the drain select lines DSL has been controlled to the target thickness that allows the impurities for reducing the resistance of the source region 117S and the drain region 117D to be implanted to the target depth. Therefore, the impurities for reducing the resistance of the source region 117S and the drain region 117D may be implanted within a projected target range Rp. N type impurities that have a higher concentration than the impurities implanted into the cell junction 117C may be used as the impurities to reduce the resistance of the source region 117S and the drain region 117D.

After the impurities are implanted into the source region 117S between the source select lines SSL and the drain region 117D between the drain select lines DSL, the first mask pattern 135 is removed.

Referring to FIG. 2F, the second insulating layer 133 is etched to form spacers 133a along sidewalls of the gate lines (SSL, WL0 to WLn, DSL, and LVN_G), respectively. The spacer 133a blocks a portion of the LDD region 129 adjacent to the gate line LVN_G in the peripheral region \textcircled{4}. N type impurities having a higher concentration than the impurities implanted into the LDD region 129 are implanted into the source and drain regions in the peripheral region \textcircled{4}, which are not blocked by the spacers 133a, by using the spacers 133a and the gate lines (SSL, WL0 to WLn, DSL, and LVN_G) as a mask, thereby forming a high-concentration N type impurity region 139.

Subsequently, a buffer layer 137 may be formed on the surface of the entire structure having the high-concentration N type impurity region 139 formed therein. The buffer layer 137 serves as a buffer that reduces substrate damage in a subsequent impurity implanting process.

After the buffer layer 137 is formed, at least one of N type impurities and P type impurities are implanted with a higher concentration than the previously implanted impurities so as to improve electrical characteristics of the source region 117S and the drain region 117D in the select transistor regions \textcircled{1} and \textcircled{3} and the source region and the drain region of the peripheral region \textcircled{4}.

Referring to FIG. 2G, a second mask pattern 149 that opens the regions between the source and drain select lines SSL and DSL is formed over the buffer layer 137. The second mask pattern 149 may be a photoresist pattern.

Referring to FIG. 2H, after exposed portions of the buffer layer 137 and the spacer 133a are etched by using the second mask pattern 149 as an etch mask, the second mask pattern 149 is removed. As a result, the thickness of the spacers 133b that remain on the sidewalls of the source and drain select lines SSL and DSL in the select transistor regions \textcircled{1} and \textcircled{3} becomes smaller than that of the spacers 133a formed in the peripheral region \textcircled{4}.

Even when the distance between the select lines SSL and the distance between the select lines DSL are reduced to achieve higher integration, the spacers 133b having a small thickness in the select transistor regions \textcircled{1} and \textcircled{3} allow for securing of a contact margin between the source and drain select lines SSL and DSL. When the thickness of the spacers 133b in the select transistor regions \textcircled{1} and \textcircled{3} is the same as that of the spacers 133a in the peripheral region \textcircled{4}, a drain contact hole is likely to be formed in an upper part of an etch stop layer that is formed along the sidewall of the spacer during a subsequent process of forming a drain contact hole. When the drain contact hole is formed in the upper part of the etch stop layer formed along the sidewall of the spacer, the drain contact hole may not expose the drain region 117D during an etch process of forming a drain contact hole. Therefore, the spacers 133b having a small thickness are formed in the select transistor regions, so as to prevent the drain contact hole failing to expose the drain region 117D.

Referring to FIG. 2I, an etch stop layer 143 is formed on the surface of the entire structure including the spacers 133b having the small thickness. The etch stop layer 143 is formed of a nitride layer.

The etch stop layer 143 is formed to reduce exposure and loss of the isolation regions B between the source regions 117S and the isolation layer 105 between the drain regions 117D during the subsequent contact hole forming process.

Referring to FIG. 2J, after a first interlayer insulating layer 145 is formed over the entire structure including the etch stop layer 143, chemical mechanical polishing (CMP) is performed to realize surface planarization of the entire structure. At this point, the first insulating layer 119, the buffer layer 137, the etch stop layer 143, and the first interlayer insulating layer 145 on the gate hard mask patterns 113 and 127 are removed. In addition, the heights of the first interlayer insulating layer 145, the spacers 133a and 133b, the first insulating layer 119, and the buffer layer 137 between the source and drain select lines SSL and DSL that are each spaced apart by a relatively large distance and at both sides of the gate line LVN_G in the peripheral region \textcircled{4} may be smaller than the height of the first insulating layer 119 in the cell region \textcircled{2}. In addition, the first interlayer insulating layer 145, the spacers 133a and 133b, the first insulating layer 119, and the buffer layer 137, which are formed of the oxide layers, between the source and drain select lines SSL and DSL and at both sides of the gate line LVN_G in the peripheral region \textcircled{4} may be removed more slowly than the etch stop layer 143 formed of the nitride layer. As a result, the etch stop layer 143 may extend/protrude higher than the first interlayer insulating layer 145, the spacers 133a and 133b, the first insulating layer 119, and the buffer layer 137.

Referring to FIG. 2K, a second interlayer insulating layer 147 is formed over the entire structure having improved surface evenness after CMP. At this point, since spaces between the etch stop layer 143 and the drain and source select lines DSL and SSL in the select transistor regions \textcircled{1} and \textcircled{3} are narrower than a space between the etch stop layer 143 and the gate line LVN_G in the peripheral region \textcircled{4}, voids 149 may be formed in the spaces between the drain and source select lines DSL and SSL and the etch stop layer 143 due to protruding portions of the etch stop layer 143.

Subsequently, a capping layer 151 and a third interlayer insulating layer 153 are sequentially formed over the second interlayer insulating layer 147.

As shown in FIG. 2L, drain contact plugs 163, source line contact plugs 161, and peripheral region contact plugs 167 are formed.

Referring to FIGS. 1 and 2L, the drain contact plugs 163 are formed in each of the first and second drain contact regions DCT1 and DCT2. When the void 149 remains in the second interlayer insulating layer 147, the void 149 may be filled with a barrier metal of the drain contact plug 163 adjacent to any one of the first and second drain select lines DSL1 and DSL2. Since the voids 149 extend in the direction in which the first and second drain select lines DSL1 and DSL2 extend, the barrier metal with which the voids 149 are filled is coupled in the direction in which the first and second drain select lines DSL1 and DSL2 extend. As a result, the drain contact plugs 163 formed in the first drain contact regions DCT1 may be electrically coupled to each other, while the drain contact plugs 163 formed in the second drain contact regions DCT2 may be electrically coupled to each other. In the first embodiment of the present invention, in order to avoid the generation of the voids 149, deposition and etch processes of the second interlayer insulating layer 147 may be repeated several times, or an additional process of opening, for example, only the select transistor regions \textcircled{1} and \textcircled{3} to remove the protruding portions of the etch stop layer 143 may be performed.

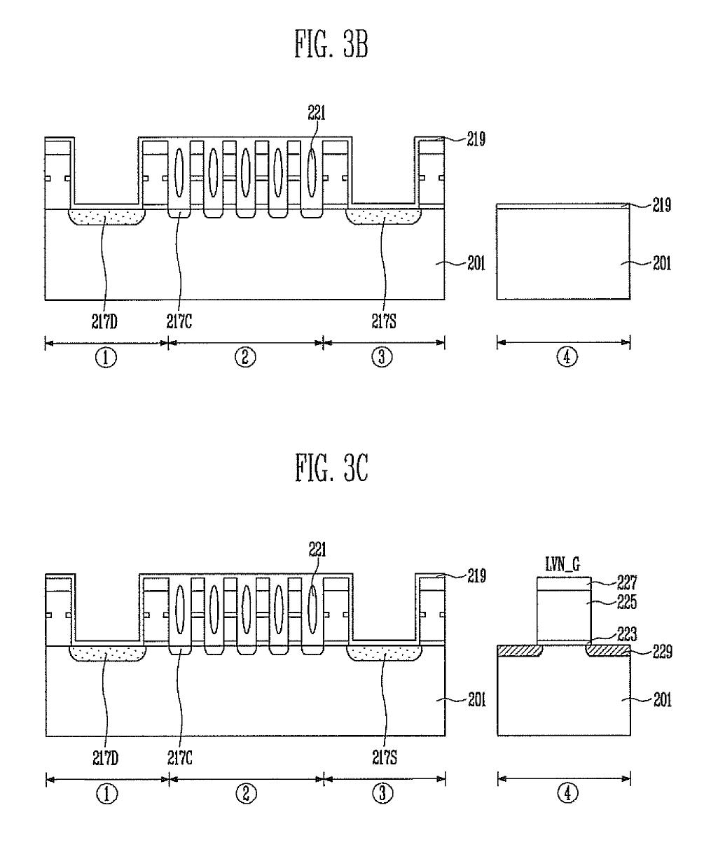

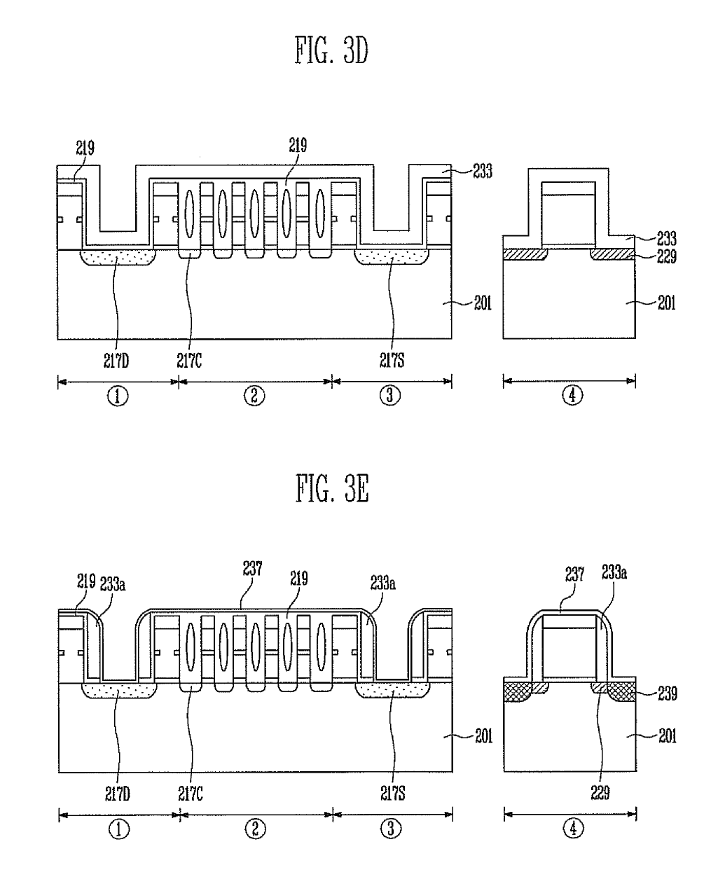

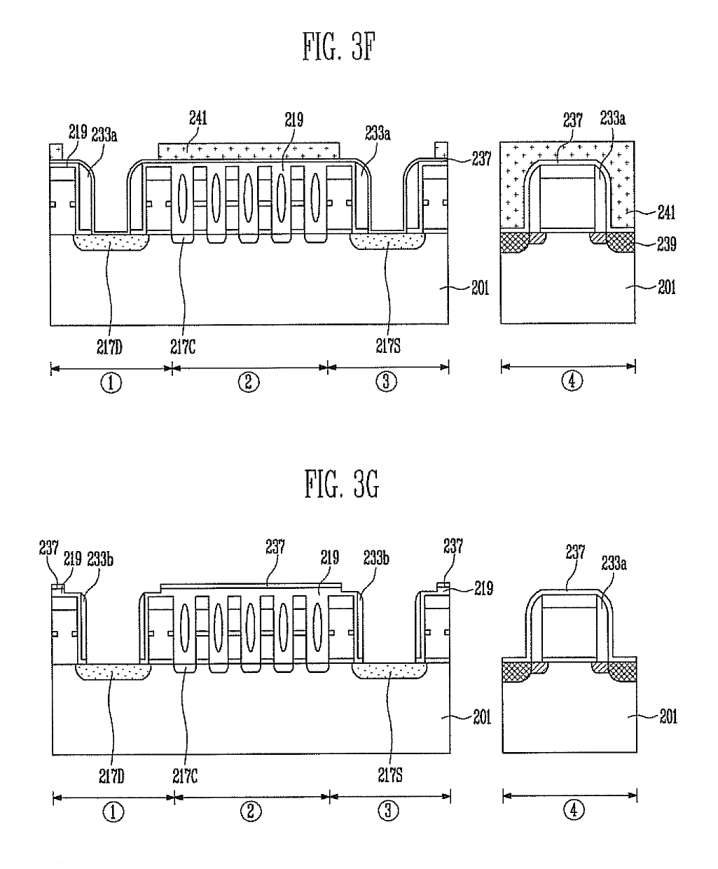

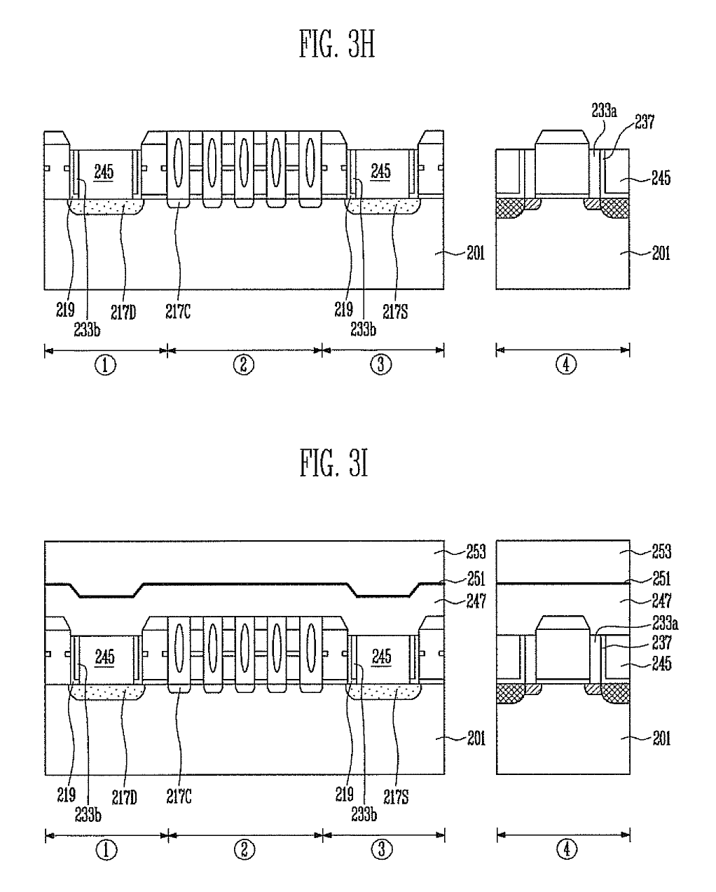

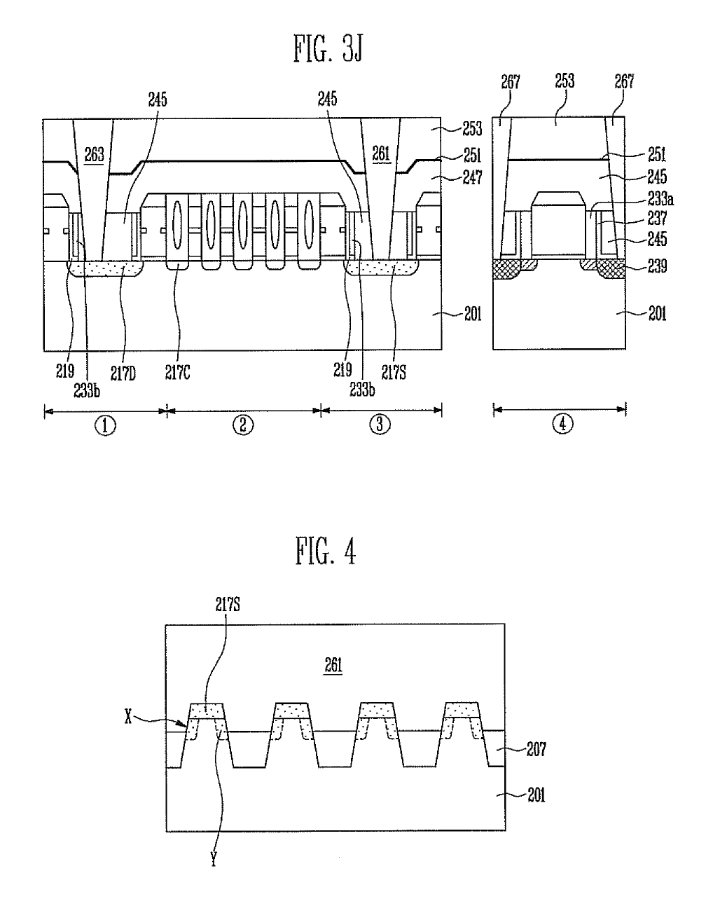

FIGS. 3A to 3J are cross-sectional views of a semiconductor device according to a second embodiment of the present invention and a method of manufacturing the same.

Referring to FIG. 3A, gate lines (SSL, WL0 to WLn, and DSL) are formed on top of a semiconductor substrate 201 that includes first to fourth regions \textcircled{1}, \textcircled{2}, \textcircled{3}, and \textcircled{4}. The first region \textcircled{1} is defined as a region in which drain select lines DSL will be formed and is defined as a region between the adjacent drain select lines DSL. The second region \textcircled{2} is defined as a region between the adjacent drain select line DSL and source select line SSL. The third region \textcircled{3} is defined as a region in which source select lines SSL will be formed and a region between the adjacent source select lines SSL. The fourth region \textcircled{4} is defined as a peripheral region. In FIGS. 3A to 3J, for example, only the region in which a low voltage NMOS transistor driven at a relatively low voltage among driving transistors forming driving circuits is formed is shown as the fourth region \textcircled{4} for illustration purposes. Hereinafter, the first and third regions \textcircled{1} and \textcircled{3} are referred to as select transistor regions, the second region \textcircled{2} is referred to as a cell region, and the fourth region \textcircled{4} is referred to as a peripheral region.

A method of forming the gate lines (SSL, WL0 to WLn, and DSL) on the semiconductor substrate 201 will now be described in more detail. In a NAND flash memory device, the gate lines including the drain select lines DSL, word lines WL0 to WLn, and the source select lines SSL are formed on top of the semiconductor substrate 201.

The following processes may be performed to form the gate lines (SSL, WL0 to WLn, and DSL).

First, a well structure (not shown) including at least any one of an n well and a p well is formed in the semiconductor substrate 201. A gate stack structure is formed on top of the semiconductor substrate 201 having the well structure formed therein. The gate stack structure has a tunnel insulating layer 203, a first silicon layer 205, a dielectric layer 209, and a second silicon layer 211 that are sequentially stacked in that order, respectively. In order to form the gate stack structure, first, the tunnel insulating layer 203 is formed over the entire surface of the semiconductor substrate 201. The first silicon layer 205 is formed over the tunnel insulating layer 203. The first silicon layer 205 may be a single layer formed of an undoped polysilicon layer or a doped polysilicon layer or may have an undoped polysilicon layer and a doped polysilicon layer that are stacked. A trivalent impurity or a pentavalent impurity may be added to the doped polysilicon layer.

Subsequently, the first silicon layer 205 is etched by an etch process using an isolation mask defining isolation regions B as an etch mask, so that the first silicon layer 205 is patterned into a plurality of parallel silicon lines. The isolation mask may be formed by using a spacer patterning technology to achieve higher integration of the device. According to the spacer patterning technology, auxiliary patterns are formed on a mask layer, spacers are formed on sidewalls of the auxiliary patterns, the auxiliary patterns are removed, and a portion of the mask layer exposed by the spacers is etched, thereby forming mask patterns. At this point, an isolation mask pattern that is formed on the select transistor regions \textcircled{1} and \textcircled{3} may be patterned by using a pad mask pattern having a larger width than the spacers as a mask, but not by using the spacers as a mask. With this spacer pattern technology, fine silicon lines can be formed in the cell region \textcircled{2} by overcoming limitations of exposure resolution.

Subsequently, the tunnel insulating layer 203 and the semiconductor substrate 201 are etched to form trenches in the form of parallel lines in the isolation regions. After an insulating layer is formed such that the trenches are filled with the insulating layer, the insulating layer on the isolation mask is removed such that the insulating layer may be left, for example, only in the trenches and on the trenches. In this manner, an isolation layer is formed.

After the isolation mask is removed, the dielectric layer 209 is formed over the entire structure. The dielectric layer 209 has an oxide layer, a nitride layer, and an oxide layer that are stacked. In addition, the oxide layer or the nitride layer may be replaced by an insulating layer that has a higher dielectric constant than itself. A portion of the dielectric layer 209 is etched in the region in which the drain and source select lines DSL and SSL will be formed. As a result, a portion of the first silicon layer 205 is exposed in the region in which the drain and source select lines DSL and SSL will be formed.

The second silicon layer 211 is formed on the dielectric layer 209. According to an example, the second silicon layer 211 may be formed of a doped polysilicon layer. In this manner, the gate stack structure is formed.

A hard mask layer 213 is formed over the gate stack structure. Subsequently, the hard mask layer 213, the second silicon layer 211, and the dielectric layer 209 are patterned in a direction crossing the silicon lines formed by patterning the first silicon layer 205. At this point, to achieve higher integration of the device, the hard mask layer 213 in the cell region \textcircled{2} may be patterned by using spacers, formed by using the spacer patterning technology, as a mask. Subsequently, the dielectric layer 209 and the second silicon layer 211 are etched. As a result, the plurality of gate lines (SSL, WL0 to WLn, and DSL) crossing the isolation regions and the active regions are formed on the semiconductor substrate 201.

After the portion of the dielectric layer 209 is etched, the second silicon layer 211 is formed. Therefore, the first silicon layer 205 and the second silicon layer 211 on the drain and source select lines DSL and SSL are electrically coupled to each other through the etched portion of the dielectric layer 209.

The distances between the adjacent word lines WL0 to WLn, the distance between the adjacent word line WL0 and source select line SSL, and the distance between the adjacent word line WLn and drain select line DSL are shorter than the distance between the adjacent drain select lines DSL and the distance between the adjacent source select lines SSL.

Cell junctions 217C are defined in the semiconductor substrate 101 in the cell region \textcircled{2} which is opened by the gate lines (SSL, WL0 to WLn, and DSL). In addition, a drain region 217D is defined in the semiconductor substrate 201 in the select transistor region \textcircled{1} which is opened between the drain select lines DSL. Also, a source region 217S is defined in the semiconductor substrate 201 in the select transistor region \textcircled{3} which is opened between the source select lines SSL.

After the gate lines (SSL, WL0 to WLn, and DSL) are formed, impurities are implanted into the cell junctions 217C. While the impurities are being implanted into the cell junctions 217C, the peripheral region \textcircled{4} is blocked by a photoresist pattern, and the impurities may also be implanted into the source and drain regions 217S and 217D. Examples of the impurities implanted into the cell junctions 217C may include N type impurities.

Subsequently, impurities are implanted into the source and drain regions 217S and 217D. While the impurities are implanted into the source and drain regions 217S and 217D, the peripheral region \textcircled{4} and the cell region \textcircled{2} are blocked by the photoresist pattern. Examples of the impurities implanted into the source and drain regions 217S and 217D may include P type impurities for counter doping. Counter doping is performed to improve electrical characteristics of the source and drain regions 217S and 217D.

Referring to FIG. 3B, a first insulating layer 219 is formed over the entire structure including the gate lines (SSL, WL0 to WLn, and DSL). According to an example, the first insulating layer 219 may be formed of an insulating layer that has an overhang structure that allows air-gaps 221 to be formed in the cell region \textcircled{2} between the gate lines (SSL, WL0 to WLn, and DSL). For example, the first insulating layer 219 is formed of a disilane-high temperature oxide (DS-HTO). The distance between the source select line SSL and the word line WL0, the distance between the drain select line DS and the word line WLn, and the distances between the word lines WL0 to WLn are shorter than the distance between the drain select lines DSL and the distance between the source select lines SSL. In addition, during the process of forming the first insulating layer 219, overhangs are formed at the top corners of the gate lines (DSL, SSL, and WL0 to WLn). For these reasons, the first insulating layer 219 does not completely fill the space between the source select line SSL and the word line WL0, the space between the drain select line DSL and the word line WLn, and the spaces between the word lines WL0 to WLn, and therefore the air-gaps 221 are formed therein. The drain select lines DSL are spaced apart by a relatively large distance, and the source select lines SSL are also spaced apart by a relatively large distance. Therefore, the first insulating layer 219 is formed between the drain select lines DSL and the source select lines SSL along the steps on the drain and source select lines DSL and SSL.

The air-gaps 221 may reduce interference between the word lines WL0 to WLn spaced apart by a short distance from one another.

The first insulating layer 219 may be non-uniform in thickness across semiconductor substrate 201. That is, the thickness of the first insulating layer 219 may be different in various regions of the semiconductor substrate 201. For example, the thickness of the first insulating layer 219 on the source region 217S and the drain region 217D arranged in the central part of the semiconductor substrate 201 may be different from that of the first insulating layer 219 on the source region 217S and the drain region 217D arranged at the edges of the semiconductor substrate 201.

Referring to FIG. 3C, after an annealing process is performed to activate the impurities implanted into the cell junction 217C, the source region 217S, and the drain region 217D, a process is performed such that a gate line LVN_G may be formed on top of the semiconductor substrate 201 in the peripheral region \textcircled{4}.

In order to form the gate line LVN_G on top of the semiconductor substrate 201 in the peripheral region \textcircled{4}, first, the first insulating layer 219 on the semiconductor substrate 201 in the peripheral region \textcircled{4} is removed. Subsequently, a gate insulating layer 223 and a gate conductive layer 225 are stacked on the semiconductor substrate 201 in the peripheral region \textcircled{4}.

After a gate mask pattern 227 is formed over the gate conductive layer 225 in the peripheral region \textcircled{4}, the gate conductive layer 225 is patterned to form the gate line LVN_G in the peripheral region \textcircled{4}.

The gate line LVN_G in the peripheral region \textcircled{4} has a greater width than the drain and source select lines DSL and SSL and the word lines WL0 to WLn. In the embodiment of the present invention, the gate line LVN_G in the peripheral region \textcircled{4} is formed by using a process separate from the process of forming the select lines DSL and SSL and the word lines WL0 to WLn. However, the gate line LVN_G in the peripheral region \textcircled{4} may be formed during the same process of forming the select lines DSL and SSL and the word lines WL0 to WLn. In this case, the gate line LVN_G in the peripheral region \textcircled{4} has the same cross-sectional structure as the select lines DSL and SSL. The gate mask pattern 227 in the peripheral region \textcircled{4} is wider than the gate mask pattern 227 in the select transistor regions \textcircled{1} and \textcircled{3} and the cell region \textcircled{2}.

Subsequently, impurities are implanted into the source region and the drain region defined on both sides of the gate line LVN_G in the peripheral region \textcircled{4} to form a lightly doped drain (LDD) region 229. The LDD region 229 of the low voltage NMOS transistor is formed by implanting N type impurities.

Referring to FIG. 3D, a second insulating layer 233 for a spacer is formed on the surface of the entire structure including the LDD region 229. The second insulating layer 233 is an insulating layer used to form spacers that block a portion of the LDD region 229 adjacent to the gate line LVN_G in the peripheral region \textcircled{4}. In addition, the second insulating layer 233 has a greater thickness than the first insulating layer 219. The second insulating layer 233 is formed of an oxide layer.

Referring to FIG. 3E, the second insulating layer 233 is etched to form spacers 233a on side walls of the gate lines (SSL, WL0 to WLn, DSL, and LVN_G), respectively. During the etch process of forming the spacers 233, the first insulating layer 219 under the second insulating layer 233 may be further etched. As a result, the drain region 217D between the drain select lines DSL and the source region 217S between the source select lines SSL are exposed. In addition, a portion of the LDD region 229 in the peripheral region \textcircled{4} is exposed.

The spacer 233a blocks a portion of the LDD region 229 adjacent to the gate line LVN_G in the peripheral region \textcircled{4}. N type impurities having a higher concentration than the impurities implanted into the LDD region 229 are implanted into the source and drain regions in the peripheral region \textcircled{4}, which are not blocked by the spacers 233a, to a depth greater than the LDD region 229 by using the spacers 233a and the gate lines (SSL, WL0 to WLn, DSL, and LVN_G) as a mask, thereby forming a high-concentration N type impurity region 239. At this point, the photoresist pattern blocking the select transistor regions \textcircled{1} and \textcircled{3} and the cell region \textcircled{2} may be used as an impurity implantation mask.

Subsequently, a buffer layer 237 may be formed on the surface of the entire structure having the high-concentration N type impurity region 239 formed therein. The buffer layer 237 serves as a buffer that reduces substrate damage in a subsequent impurity implanting process. In addition, the buffer layer 237 is formed of an oxide layer.

After the buffer layer 237 is formed, N type impurities and P type impurities are implanted so as to improve electrical characteristics of the source region 217S and the drain region 217D in the select transistor regions \textcircled{1} and \textcircled{3} and the source region and the drain region in the peripheral region \textcircled{4}.

Subsequently, an annealing process is performed to activate the implanted impurities.

Referring to FIG. 3F, a second mask pattern 241 that opens the buffer layer 237 and the spacers 233a in the select transistor regions \textcircled{1} and \textcircled{3} is formed. The second mask pattern 241 may be a photoresist pattern.

Referring to FIG. 3G, the buffer layer 237, the spacers 233a, and the first insulating layer 219 exposed by the mask pattern 241 are etched by wet etching to expose the source region 217S between the source select lines SSL and the drain region 217D between the drain select lines DSL. During deposition of the first insulating layer 219, the thickness of the first insulating layer 219 may be different in various regions of the semiconductor substrate 201, so that the first insulating layer 219 may remain at the top of some of the source region 217S and the drain region 217D after wet etching is completed. However, the first insulating layer 219 that remains is reduced to a thickness, due to wet etching, which does not affect a projected range (Rp) during a subsequent impurity implanting process. In addition, the thickness of the spacers 233b left on the sidewalls of the select lines DSL and SSL becomes smaller than that of the spacers 233a the peripheral region \textcircled{4}.

Subsequently, impurities are implanted into the drain region 217D between the drain select lines DSL and the source region 217S between the source select lines SSL to reduce resistance. At this point, N type impurities having a concentration higher than the concentration of the impurities implanted into the cell junction 217C are implanted. Since the thickness of the first insulating layer 219 has been reduced or removed, the impurities for reducing the resistance of the source region 217S and the drain region 217D may be implanted at a target Rp. After the impurities for reducing resistance are implanted into the source region 217S between the drain select lines DSL and the drain region 217D between the source select lines SSL, the mask pattern 241 is removed. Subsequently, an annealing process is performed to activate the implanted impurities.

Referring to FIG. 3H, a first interlayer insulating layer 245 is formed over the entire structure from which the mask pattern 241 is removed, without forming an etch stop layer. As a result, the first interlayer insulating layer 245 comes in direct contact with the spacer 233b in the select transistor regions \textcircled{1} and \textcircled{3}. The first interlayer insulating layer 245 may be formed of an oxide layer.

Chemical mechanical polishing (CMP) is performed to realize surface planarization of the entire structure. At this point, the first insulating layer 219, the buffer layer 237, and the first interlayer insulating layer 245 on the gate hard mask patterns 213 and 227 are removed. The density of the gate lines (SSL, WL0 to WLn, DSL, and LVN_G) is lower in the select transistor regions \textcircled{1} and \textcircled{3} and the peripheral region \textcircled{4} than in the cell region \textcircled{2}. Therefore, after surface planarization, the heights of the first interlayer insulating layer 245, the spacers 233a and 233b, the first insulating layer 219, and the buffer layer 237 in the select transistor regions \textcircled{1} and \textcircled{3} and the peripheral region \textcircled{4} may be smaller than the height of the first insulating layer 219 in the cell region \textcircled{2}. In the second embodiment of the present invention, since an etch stop layer is not formed, a phenomenon in which the etch stop layer extends higher than a neighboring oxide layer and is left due to the selectivity difference between an oxide layer and a nitride layer does not occur.

Referring to FIG. 3I, a second interlayer insulating layer 247 is formed over the entire structure having improved surface evenness after CMP. In the second embodiment of the present invention, since protruding portions of an etch stop layer are not formed, voids created by the protruding portions of the etch stop layer are not formed in the second interlayer insulating layer 247. The second interlayer insulating layer 247 may be formed of an oxide layer.

Subsequently, a capping layer 251 is formed on the second interlayer insulating layer 247. The capping layer 251 is formed to block electrons or hydrogen ions from moving between structures above and under the capping layer 251 and affecting retention characteristics. According to an example, the capping layer 251 may be formed of a nitride layer.

A third interlayer insulating layer 253 is formed over the capping layer 251. In this manner, an interlayer insulating stack structure (245, 247, 251, and 253) is formed to insulate the gate lines (SSL, WL0 to WLn, DSL, and LVN_G) and the metal wiring formed thereon from each other.

Referring to FIGS. 1 and 3J, a drain contact hole that exposes the drain region 217D is formed in each of the first and second drain contact regions DCT1 and DCT2 in which drain contact plugs 263 will be formed. In addition, a source contact hole that exposes the source region 217S and an isolation layer 207 is formed in the source contact region SCT in which a source contact plug 261 will be formed. In addition, peripheral contact holes that expose the high-concentration N type impurity region 239 in the peripheral region \textcircled{4} are formed in portions in which peripheral contact plugs 267 in the peripheral region \textcircled{4} will be formed.

As described above, while the contact holes including the drain contact hole, the source contact hole, and the peripheral contact holes are formed, a primary etch process is performed by using the capping layer 251, formed of a nitride layer, as an etch stop layer; a secondary etch process is performed to remove an exposed portion of the capping layer 251; and a tertiary etch process is performed to remove exposed portions of the second interlayer insulating layer 247 and the first interlayer insulating layer 245. The drain contact hole, the source contact hole, and the peripheral contact holes may be formed by using separate primary to tertiary etch processes.

Subsequently, impurities having a higher concentration than the impurities implanted into the respective junctions (217S, 217D, and 239) in the previous process are further implanted into the surface of the semiconductor substrate 201 exposed through the contact holes, thereby further reducing the resistance of the respective junctions (217S, 217D, and 239). Since the junctions (217S, 217D, and 239) according to the second embodiment of the present invention are shown by exemplifying an NMOS device, N type impurities are implanted thereinto.

Subsequently, the contact holes are filled with a conductive layer to form the drain contact plug 263 connected to the drain region 217D, the source contact plug 261 connected to the source region 217S, and the peripheral contact plugs 267 connected to the source region and the drain region in the peripheral region \textcircled{4}. A metal layer formed of tungsten or copper may be used as the conductive layer with which the contact holes are filled. A barrier metal layer such as a titanium nitride layer may be further formed to suppress diffusion in metals before the conductive layer is formed.

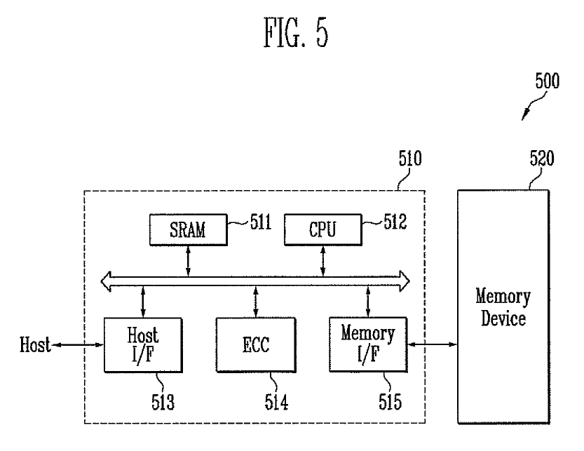

FIG. 4 is a cross-sectional view of the semiconductor device according to the second embodiment of the present invention, taken in a direction of a source contact line.

In the second embodiment of the present invention, an etch stop layer is not formed unlike the first embodiment. Therefore, as described above in connection with FIG. 3J, the tertiary etch process is performed without performing an etch stop process using an etch stop layer. Therefore, as shown in FIG. 4, the isolation layer 207 may not be protected by an etch stop layer and may be lost during the tertiary etch process (especially, a tertiary etch process of forming a source contact hole). As a result, the height of the isolation layer 207 becomes smaller than the surface height of the active region A of the semiconductor substrate 201, so that the sidewall of the active region A and the sidewall of the well structure of the semiconductor substrate 201 are exposed to form a region indicated by reference character X. At this point, resistance may be increased in a portion where the region, indicated by reference character X, comes in contact with the source contact plug 261. In order to avoid the increase in resistance, according to an example, a junction extension Y is further formed on the sidewall of the active region A of the semiconductor substrate 201, which is exposed by removing the isolation layer 207, by using an impurity implantation process before the contact hole is filled with the source contact plug 261. The junction extension Y may be formed in the active region A, which is a junction, under the source region 217S by tilting an impurity implantation angle. In this manner, in the present invention, an increase in contact resistance between the source contact plug 261 and the active region A caused by omitting the forming of the etch stop layer can be avoided by forming the junction extension Y. The process of forming the junction extension Y to avoid the increase in contact resistance may be performed on the active region A under the drain region 217D which comes in contact with the drain contact plug 263 as well as the active region A under the source region 217S which comes in contact with the source contact plug 261.

FIG. 5 is a schematic block diagram of a memory system according to an exemplary embodiment of the present invention.

Referring to FIG. 5, a memory system 500 according to an embodiment of the present invention includes a memory device 520 and a memory controller 510.

The memory device 520 includes the semiconductor memory device manufactured by using the processes described in connection with FIGS. 3A to 3J and FIG. 4. That is, the memory device 520 includes select lines formed on a semiconductor substrate including active regions separated by an isolation layer, and arranged in a direction crossing the active regions; junctions formed by implanting first impurities into the active regions between the select lines; junction extensions coupled under the junctions, formed in the active regions of the semiconductor substrate, and formed by implanting second impurities; and contact plugs coming in contact with the junctions and the junction extensions. In addition, a nitride layer is not disposed in spaces between the select lines of the memory device 520, but a plurality of oxide layers are formed therein. The contact plugs pass through at least one of the plurality of oxide layers with which the spaces between the select lines are filled.

The memory controller 510 controls data exchange between a host and the memory device 520. The memory controller 510 may include a processing unit 512 that controls the general operation of the memory system 500. In addition, the memory controller 510 may further include an SRAM 511 that is used as an operating memory of the processing unit 512. Also, the memory controller 510 may further include a host interface 513 and a memory interface 515. The host interface 513 may include a data exchange protocol between the memory system 500 and the host. The memory interface 515 may couple the memory controller 510 and the memory device 520 to each other. The memory controller 510 may further include an error code correction (ECC) block 514. The ECC block 514 may detect and correct an error in data read from the memory device 520. Though not shown in FIG. 5, the memory system 500 may further include a ROM device that stores code data for an interface with the host. The memory system 500 may be used as a portable data storage card. In contrast, the memory system 500 may be implemented using a solid state disk (SSD) that can replace a hard disk of a computer system.

According to exemplary embodiments of the present invention, spaces between gate lines can be filled, for example, only with insulating layers formed of oxide layers by not forming an etch stop layer formed of a nitride layer before the spaces between the gate lines are filled with interlayer insulating layers. Accordingly, any one of the insulating layers with which the spaces between the gate lines are filled may be prevented from protruding and remaining even after a planarization process is performed on the interlayer insulating layers, thereby avoiding generation of voids caused by protruding portions of the insulating layer.

In addition, extensions of junctions are formed by implanting impurities into active regions of a semiconductor substrate exposed due to loss of an isolation layer during an etch process of forming a contact hole, so that an increase in contact resistance between contact plugs formed in the contact holes and the active regions of the semiconductor substrate.

What is claimed is:

1. A semiconductor device, comprising:
a semiconductor substrate including active regions extending in a first direction;
select lines provided on the semiconductor substrate in a second direction crossing the first direction;
junctions provided on the active regions, respectively, between the select lines and including first impurities;
a plurality of oxide layers filling spaces between the select lines;
junction extensions coupled under the junctions and provided on the active regions of the semiconductor substrate, wherein the junction extensions include second impurities; and
contact plugs passing through at least one of the plurality of oxide layers and coming in contact with the junctions and the junction extensions.

2. The semiconductor device of claim 1, wherein the junction extensions are provided on sidewalls of the active regions, respectively.

3. The semiconductor device of claim 1, wherein the second impurities have a higher impurity concentration than the first impurities.

4. The semiconductor device of claim 1, wherein the contact plugs extend in a direction of the select lines.

5. The semiconductor device of claim 1, wherein the select lines include first and second drain select lines, and
the contact plugs include first drain contact plugs adjacent to the first drain select line and coupled to odd-numbered active regions among the active regions arranged in a direction of the first and second drain select lines and include second contact plugs adjacent to the second drain select line and coupled to even-numbered active regions among the active regions arranged in the direction of the first and second drain select lines.

6. The semiconductor device of claim 1, further comprising word lines spaced apart by a shorter distance than the select lines and arranged next to the select lines on the semiconductor substrate.

7. The semiconductor device of claim 6, wherein the plurality of oxide layers comprise;
a first oxide layer defining air-gaps between the word lines, wherein the first oxide layer is provided between the word lines and provided along sidewalls of the select lines;
a second oxide layer for a spacer formed along the sidewalls of the select lines over the first oxide layer; and
a third oxide layer filled between the select lines.

8. The semiconductor device of claim 7, further comprising:
a first interlayer insulating layer formed over the third oxide layer, wherein the contact plugs pass through the first interlayer insulating layer;
a capping layer formed over the first interlayer insulating layer, wherein the contact plugs pass through the capping layer; and
a second interlayer insulating layer formed over the capping layer, wherein the contact plugs pass through the second interlayer insulating layer.

9. The semiconductor device of claim 8, wherein the first and second interlayer insulating layers are oxide layers, and the capping layer is a nitride layer.

10. A method of manufacturing a semiconductor device, the method comprising:
forming select lines extending in a second direction crossing a first direction on a semiconductor substrate, wherein the semiconductor substrate has active regions separated by an isolation layer and extending in the first direction;
forming junctions by implanting first impurities into the active regions, respectively, between the select lines and forming a plurality of oxide layers filled between the select lines;
forming contact holes exposing the junctions by etching at least one of the plurality of oxide layers;
forming junction extensions by implanting second impurities into the active regions of the semiconductor substrate exposed due to loss of the isolation layer while the contact holes are formed; and
forming contact plugs for filling the contact holes.

11. The method of claim 10, wherein the forming of the junction extensions comprises implanting the second impurities into sidewalls of the active regions.

12. The method of claim 10, wherein word lines spaced apart by a smaller distance than the select lines are further formed during the forming of the select lines.

13. The method of claim 12, wherein the forming of the junctions and the plurality of oxide layers comprises:
forming a first oxide layer over an entire structure having the select lines and the word lines formed thereon, wherein the first oxide layer defines air-gaps between the word lines and is formed along sidewalls of the select lines;
forming a second oxide layer along the sidewalls of the select lines for a spacer over the first oxide layer;
etching the second oxide layer and the first oxide layer between the select lines to expose the active regions between the select lines;
implanting the first impurities into the active regions between the select lines;
forming a third oxide layer filled between the select lines; and
planarizing the entire structure having the third oxide layer formed thereon.

14. The method of claim 10, wherein a concentration of the first impurities is higher than a concentration of the second impurities.

15. The method of claim 10, wherein the second impurities are further implanted into the junctions exposed through the contact holes.

16. The method of claim 10, wherein the contact plugs extend in a direction of the select lines and are commonly coupled to the isolation layer and the active regions.

17. The method of claim 10, wherein the select lines include first and second drain select lines, and
the contact plugs include first drain contact plugs adjacent to the first drain select line and coupled to odd-numbered active regions among the active regions arranged in a direction of the first and second drain select lines and include second drain contact plugs adjacent to the second drain select line and coupled to even-numbered active regions among the active regions arranged in the direction of the first and second drain select lines.

18. The method of claim 10, further comprising:
forming a first interlayer insulating layer formed of an oxide layer over an entire structure having the plurality of oxide layers formed thereon before the forming of the contact holes;
forming a capping layer formed of a nitride layer over the first interlayer insulating layer; and
forming a second interlayer insulating layer formed of an oxide layer over the capping layer.
